(19) United States
(12) Patent Application Publication
(10) Pub. No.: US 2006/0020429 A1
(43) Pub. Date: Jan. 26, 2006

(54) Method and apparatus for configuring interfaces for automated systems

(76) Inventors: Ruven Brooks, Shorewood, WI (US); David Grooms, Delafield, WI (US); Keith McRitchie, Wolfsbach (AT); Marek Obitko, Dobrichovice (CZ)

Correspondence Address: ROCKWELL AUTOMATION, INC./(QB), ATTENTION: SUSAN M. DONAHUE, 1201 SOUTH SECOND STREET, MILWAUKEE, WI, 53204, US

(21) Appl. No.: 11/145,095

(22) Filed: Jun. 3, 2005

Related U.S. Application Data
(63) Continuation-in-part of application No. 10/674,588, filed on Sep. 30, 2003.
Application No. 10/674,588 is a continuation-in-part of application No. 10/614,634, filed on Jul. 7, 2003.
Application No. 10/614,634 is a continuation of application No. 10/304,190, filed on Nov. 26, 2002, now Pat. No. 6,862,553.
Application No. 10/304,190 is a continuation of application No. 09/410,270, filed on Sep. 30, 1999, now Pat. No. 6,556,950.

(51) Int. Cl. H03F 1/26; G06F 11/30; H04B 15/00; G06F 15/00

(52) U.S. Cl. 702/189; 702/183

(57) ABSTRACT

An apparatus and method for configuring an interface for use with an automated system including at least a first controller that runs a first system program to control and monitor automated system components, a first project file associated with the first system program and describing at least a subset of the system components and system operation, the method comprising the steps of providing an interface template that specifies interface components and arrangement of the interface components relative to each other for presentation on a display screen, gleaning information from the first project file regarding input and output parameters to be supported by an interface and instantiating an instance of an interface using the interface template and the information gleaned from the first project file.

### CROSS-REFERENCE TO RELATED APPLICATIONS

This is a continuation-in-part of U.S. patent application Ser. No. 10/674,588 which was filed on Sep. 30, 2003 and is titled “Mechanical-Electrical Template Based Method and Apparatus” which was a continuation-in-part of U.S. patent application Ser. No. 10/614,634 which was filed on Jul. 7, 2003 and is titled “Simulation Method and Apparatus for Use in Enterprise Controls” which was a continuation of U.S. patent application Ser. No. 10/304,190 which was filed on Nov. 26, 2002 and is titled “Diagnostics Method and Apparatus for Use with Enterprise Controls” which was a continuation of U.S. patent application Ser. No. 09/410,270 which was filed on Sep. 30, 1999 which issued on Apr. 29, 2003 as U.S. Pat. No. 6,556,950 and is also titled “Diagnostics Method and Apparatus for Use with Enterprise Controls”. Each of the above-referenced applications and patent is incorporated here and by reference in its entirety.

### STATEMENT REGARDING FEDERALLY SPONSORED RESEARCH OR DEVELOPMENT

Not applicable.

### BACKGROUND OF THE INVENTION

The field of the invention is human-machine interfaces for an automated system and more specifically systems and methods for streamlining the interface specifying process using information gleaned from a project file that is already generated for other purposes.

A typical automated manufacturing system includes mechanical and electrical components that are configured to perform a specific manufacturing process such as, for instance, assembling at least a portion of a specific type of automobile. In addition, a typical system also includes one or more processor based controllers linked to the other system components for controlling and monitoring process operation. Moreover, a typical system also includes one or more human-machine interfaces that facilitate operator control and monitoring of the system components. Here, the interfaces are linked to the controllers for receiving information therefrom and providing control information thereto.

While early interface configurations employed a myriad of different types of mechanical push buttons, switches, dials, slide buttons, light devices (e.g., incandescent lights, LEDs, etc.), audio devices, digital dial type read outs, etc., recently display screens (e.g., flat panel plasma, LED, etc.) have been adopted for use as automated system interface components. Here, it has generally been recognized in the industry that software to drive display devices can be written such that a single display screen package can be configured to support many different system configurations and to simulate many different types of more traditional interface components (e.g., buttons, switches, output devices, etc.) thereby reducing overall interface costs appreciably.

For example, in a first instance interface software may be written to configure a screen based interface device including input icons (i.e., icons that simulate buttons, switches, dials, etc.), output icons (i.e., icons that simulate warning lights, status lights, etc.) and output text for controlling/monitoring an automobile assembly system and in a second instance other interface software may be written to configure the same screen based interface device to include input and output icons and output text for controlling/monitoring a powder coating and drying manufacturing system, despite the fact that the input and output devices and output diagnostic text required to support the two systems may be completely different. Here, in addition to the screen, an interface assembly may include an audio output device such as a small speaker or the like where the audio output device, like the display screen, can be driven differently to support various types of applications.

While display screen based interface devices are extremely useful when configured properly, such devices still have several shortcomings. First, the process of configuring an interface device for a specific automated system is extremely costly. In this regard, the process of configuring an interface device begins with a software engineer analyzing an automated process to be performed and identifying input and output parameters that should be supported by an interface to be configured. Next, after system code to be run by the system controllers to control/monitor the automated system components has been written, the engineer has to examine the system code to identify the controller memory addresses associated with the input and output parameters that are to be supported by the interface.

After identifying controller memory addresses associated with the input and output parameters, the engineer has to select input icons (e.g., button, switch, etc. icons) and output icons (i.e., LED simulating, color changing icons, etc.) and specify output text for each of the required inputs and outputs. Here, for instance, a software package may include push buttons having tens if not hundreds of different operating characteristic combinations as well as hundreds of different appearances (e.g., sizes, colors, shapes, etc.). Similarly, the engineer is free to specify any diagnostic or informational text string(s) as output related to certain types of operations. For instance, where a specific operating error occurs, the engineer may specify any text string to be presented via the interface to indicate the operating error.

After input and output icons and output text have been identified, the engineer next has to determine how to arrange the icons and textual output on the display screen. Continuing, the engineer has to link the input and output parameter addresses to the correct screen displayed icons so that the parameters can control and can be controlled by appropriate icons.

In addition, the engineer has to script activities associated with specific screen selectable icons (e.g., push button simulating icons, sliding button icons, etc.). For instance, different selectable button icons may be provided for each of several different stations that comprise a machine line where, when one of the station selecting buttons is selected, the interface is supposed to present information associated with the specific station. Here, when a station button is selected a tag change event occurs as the value of a tag associated with the button is altered (e.g., may be changed from 1 to 0 or vice versa) and activities associated with the specific event need to be scripted. As another instance, different selectable button icons may be provided for each of several different types of informational views where, when one of the view selecting buttons is selected, the interface is supposed to present information associated with the selected view type. Here, when a view type button is selected a page change event occurs and an entirely differently formatted interface has to be scripted. In addition to being caused by operator activity, tag and page change events can also be precipitated by controller activities during operation.

While this process may not appear extremely burdensome in the case of a simple automated system including a small number of components, in the case of a more complex automated system including several different automated sections, stations and substations, multi-layer interfaces are often required to provide all of the control and monitoring input and output icons required to support the system. In many cases it has been observed that the process of specifying a single interface for a complex system can take several days and even weeks of a highly skilled engineer's time to complete. Moreover, in many cases several (e.g., ten or more) interfaces may be required to support a single automated system and the task of configuring all of the separate interface devices exacerbates the process and increases costs appreciably.

Complicating the HMI programming task further, in the past there has been no known software package that is well suited to the task of facilitating scripting required to specify HMI activities associated with change events (i.e., tag change or page change events). In this regard, one way previously used to script HMI activities has been to use a general purpose scripting language such as Visual Basic for Applications. While general purpose scripting language has been used with some success in the past, unfortunately use of a general language for scripting HMI activities has several shortcomings. First, using a general scripting language requires that a programmer write a huge amount of code which is time consuming, is relatively complicated to debug and hence is burdensome to generate. Second, in many cases it has been observed that using a general scripting language to script HMI activities results in code that requires a huge amount of runtime memory during execution and that can be too burdensome for some HMI terminals that have limited memory resources.

Second, because the interface specifying process is often complex, engineers routinely make errors along the way which are only apparent at a later time when the interface is tested. Thus, interface debugging can be extremely burdensome and further increases overall interface development costs.

Third, where separate and distinct processes are required to provide many different interfaces for use in a single facility or for a single automated system, the distinct processes often result in interfaces that have different appearances and that, in some cases, function in different ways. For instance, in a large facility that includes 200 different interfaces, the interfaces may have been developed over a long period (e.g., 7 years) and, even if all of the interfaces were developed by the same engineer, appearance and functionality preferences may have evolved such that intra-facility interfaces will have different appearances and functionality. Where each of several engineers separately developed sub-sets of the 200 interfaces, interface differences (i.e., appearance and functionality) will usually be even more profound. While each of the different interfaces may be functional, for end users, standardization is advantageous so that a user familiar with one interface layout, look and feel and functionality can more easily interact with other interfaces within the same facility. Where interfaces have multiple appearances and different functionality end use is more difficult and hence increases end user training costs.

Thus, it would be advantageous to have a method and system for streamlining interface development, reducing development and debugging time required and generating interfaces that have consistent looks and feels and functionality.

### BRIEF DESCRIPTION OF THE SEVERAL VIEWS OF THE DRAWINGS

FIG. 1 is a schematic diagram of a system according to at least one embodiment of the present invention;

FIG. 2 is a schematic diagram illustrating control assemblies associated with one of the stations that form the automated assembly of FIG. 1;

FIG. 3 is an image of a screenshot that may be provided via one of the HMIs of FIG. 1;

FIG. 4 is similar to FIG. 3, albeit illustrating a second screenshot provided when a specific combination of buttons is selected via the FIG. 3 screen shot;

FIG. 5 is a flow chart for specifying or defining an interface template according to at least one embodiment of the present invention;

FIG. 6 is a flow chart illustrating a method for generating a HMI program for use in driving a human-machine interface according to at least one embodiment of the present invention;

FIG. 7 is a screenshot consistent with a second embodiment of the invention that may be provided via one of the HMIs of FIG. 1; and

FIG. 8 is a schematic diagram illustrating an exemplary project file that is useful in performing at least some aspects of the present invention.

### DETAILED DESCRIPTION OF THE INVENTION

One or more specific embodiments of the present invention will be described below. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

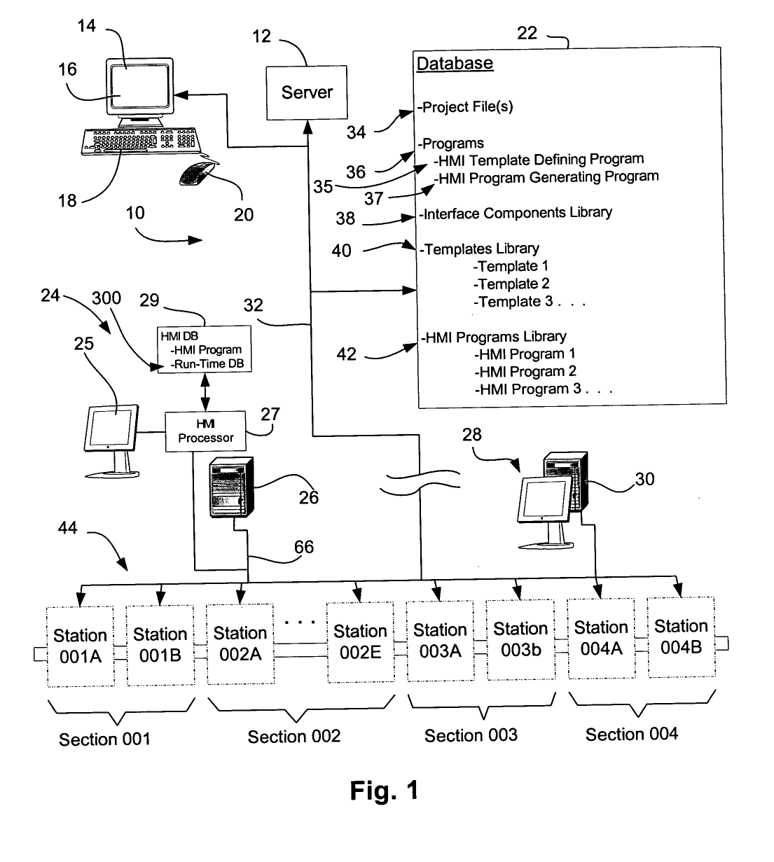

Referring now to the drawings wherein like reference numerals correspond to similar elements throughout the several views and, more specifically, referring to FIG. 1, the present invention we described in the context of an exemplary interface configuring system 10 for use in configuring interfaces to be used to control an exemplary automated system 44. Exemplary automated system 44 includes a plurality of workstations 001A, 001B, 002A, 002E, 003A, 003B, 004A and 004B, first and second controllers 26 and 30 and first and second interface devices 24, 28, respectively. The workstations (e.g., 001A, 001B, 002A, etc.) are arranged along a manufacturing line (not numbered) to perform an automated process (e.g., an engine assembly process). The stations are divided into line sections, four of which are labeled Sections 001, 002, 003 and 004. Each of the sections includes a plurality of stations. For example, Section 001 includes stations 001A and 001B while Section 002 includes stations 002A through 002E, Section 003 includes stations 003A and 003B, etc.

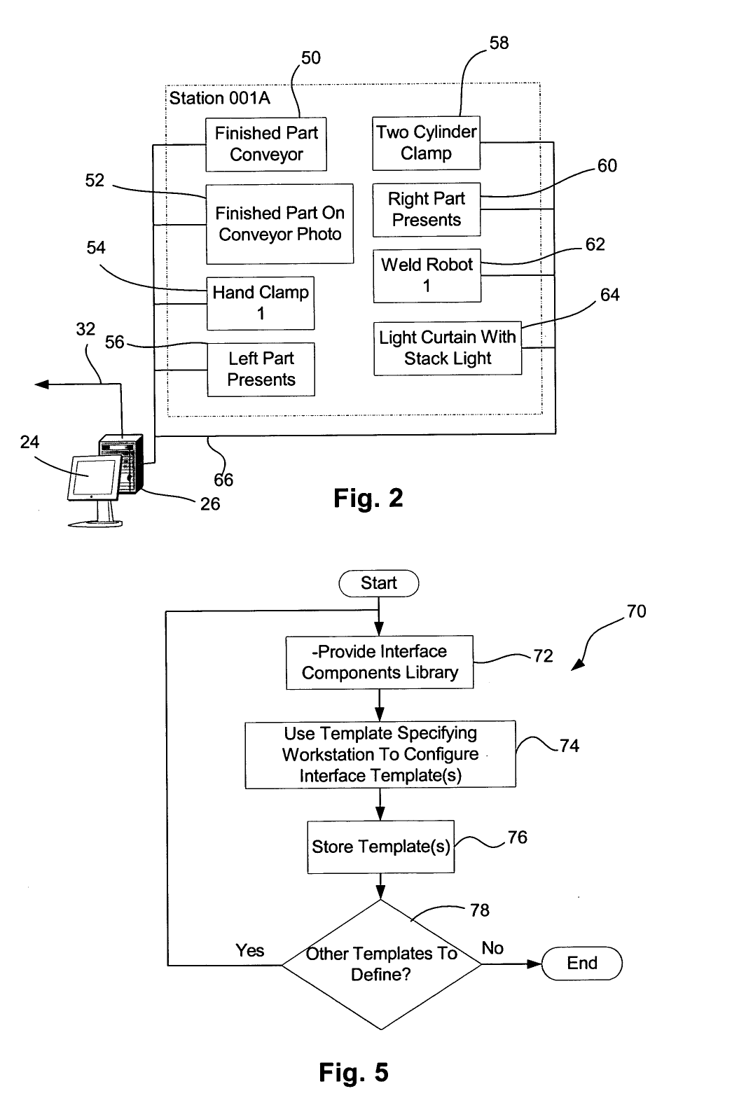

Referring still to FIG. 1, each station includes a plurality of different control assemblies which include mechanical and electrical components that are configured to perform a portion of the overall manufacturing process and/or to monitor a portion of the manufacturing process. For example, referring also to FIG. 2, exemplary station 001A includes a finished part conveyor 50, a finished part on conveyor photo assembly 52, a hand clamp 54, a left part presents assembly 56, a two cylinder clamp 58, a right part presents assembly 60, a weld robot assembly 62 and a light curtain with stack light assembly 64.

In the illustrated embodiment, each of the control assemblies corresponding to Section 001 is linked to an information network 66 (e.g., an Ethernet, ControlNet, etc.). Similarly, referring to FIG. 1, each of the control assemblies associated with the other automated system stations (e.g., 001B, 002A, etc.) is also linked to network 66. Controllers 26 and 30 are linked to network 66 and can be used, if programmed appropriately, to control/monitor any subset of the station resources (i.e., control assemblies) within system 44. Throughout this specification, unless indicated otherwise, it will be assumed that controller 26 is programmed to control station resources associated with sections 001 and 002 (e.g., stations 001A, 001B, 002A, . . . 002E, etc.) while controller 30 is programmed to control station resources associated with sections 003 and 004 (i.e., stations 003A, 003B, 004A and 004B).

Referring still to FIG. 1, interfaces 24 and 28 are linked to network 66 for monitoring system 44 operations and for receiving operator input for controlling system 44 resources. In FIG. 1, interface 24 is shown adjacent controller 26 to indicate that interface 24 is, in the example, provided to control/monitor station resources that are controlled by controller 26. Similarly, interface 28 is shown adjacent controller 30 to shown a functional relationship in the present example. Nevertheless, it should be appreciated that, in some cases, interfaces 24 and 28 may be remote from controllers 26 and 30 and may be programmed to control/monitor different station resource subsets.

Hereinafter, interfaces 24 and 28 will be referred to as human-machine interfaces (HMIs), code or software run by each HMI to facilitate interfacing functionality will be referred to as HMI programs and code run by automated assembly controllers 26 and 30 to control/monitor sub-sets of assembly 44 station resources will be referred to as controller code unless indicated otherwise. In addition, in the interest of simplifying this explanation, unless indicated otherwise, the inventions contemplated will be described in the context of HMI 24 and controller 26. Here, it should suffice to say that it is contemplated that at least some of the inventive methods to be described will be performed separately for each automated system HMI (e.g., 24, 28, etc.).

In the illustrating embodiment, HMI 24 includes a flat touch screen panel 25, an HMI processor 27 and an HMI memory device 29 where processor 27 is linked to each of panel 25 and device 29. Although not illustrated it is contemplated that HMI 28, in at least some embodiments, would also include a processor and HMI database. Panel 25 has a front facing display screen and a sensor configuration for sensing the contact location on screen 25 when an operator touches screen 25 (e.g., the location of a user's finger tip). Touch sensitive display screens like screen 25 are well known in the computing arts and therefore will not be described here in detail. An HMI program is stored in device 29 that is run by processor 27 to provide interface information to a user via screen 25. In addition, in at least some inventive embodiments, an Active-X database (described below) is stored in memory device 29 for use by processor 27.

Referring to FIG. 1, interface configuring system 10 includes a server 12, a database 22, an operator workstation 14 and a network 32 that links server 12, workstation 14 and database 22 together. Network 32 is also linked or is linkable to network 66 so that server 12 can download HMI programs to HMIs 24 and 28.

Server 12 is a processor based computing device that runs software to perform various functions that are consistent with at least some aspects of the present invention. To this end, in general, server 12 runs a program enabling a workstation 14 operator to define one or more interface templates for subsequent use to relatively automatically generate instances of HMI software used to drive HMI 24, 28, etc. In addition, in at least some embodiments, server 12 runs a program for instantiating instances of HMI programs using the interface templates as well as information gleaned from “project files” associated with controller code.

Referring to FIG. 1, database 22 stores data and programs used by server 12 to perform the inventive methods. While shown as a simple database, it should be appreciated that database 22 may take any of several different forms including a relational configuration, a configuration where programs and data are stored separately, a configuration where different programs are stored on different databases, etc. Exemplary database 22 stores programs 36 and an interface components library 38. Exemplary programs include a template defining program 35 (hereinafter the “template program”) and an HMI program generating program (hereinafter the “HMI generating program”). In addition, after templates are defined, database 22 stores the templates in a template library 40 and, after HMI programs have been instantiated, database 22 stores the instantiated HMI in a HMI programs library 42. Moreover, in the illustrated embodiment, database 22 stores one or more project files that are described in greater detail below.

Referring still to FIG. 1, workstation 14 includes a display screen 16, a processor (not illustrated) and interface/input devices such as keyboard 18 and mouse 20. Screen 16 is used to present information to a workstation operator useful in configuring templates and HMI programs. The operator uses devices 18 and 20 to provide template and interface specifying information.

U.S. Pat. No. 6,268,863 that is titled Data Structure For Use in Enterprise Controls describes the project file concept and is incorporated herein by reference. Referring still to FIG. 1, for the purposes of this disclosure, it should suffice to say that project files 34 are intermediate data constructs that are generated by known interactive software packages that are in turn used to generate controller code to be run by assembly controllers 26, 30, etc. Various types of interactive software packages have been developed that allow a user to relatively intuitively specify control assembly information. For instance, one known interactive software package for specifying automated assembly characteristics is the “RS Enterprise Control” software package currently produced and sold by Rockwell Software, Inc. As automated system characteristics are specified using an interactive software package, the package converts the specified information into a project file consistent with the specified information. An exemplary project file includes labels corresponding to an associated controller and information related to automated system resources to be controlled by the controller including system sections (e.g., sections 001, 002, etc., in FIG. 1), stations and control assemblies as well as I/O assignments, a set of hierarchical levels for organizing the control assemblies and determining their modes of behavior, sequential and asynchronous flow of control mechanisms and permissives for manual operations.

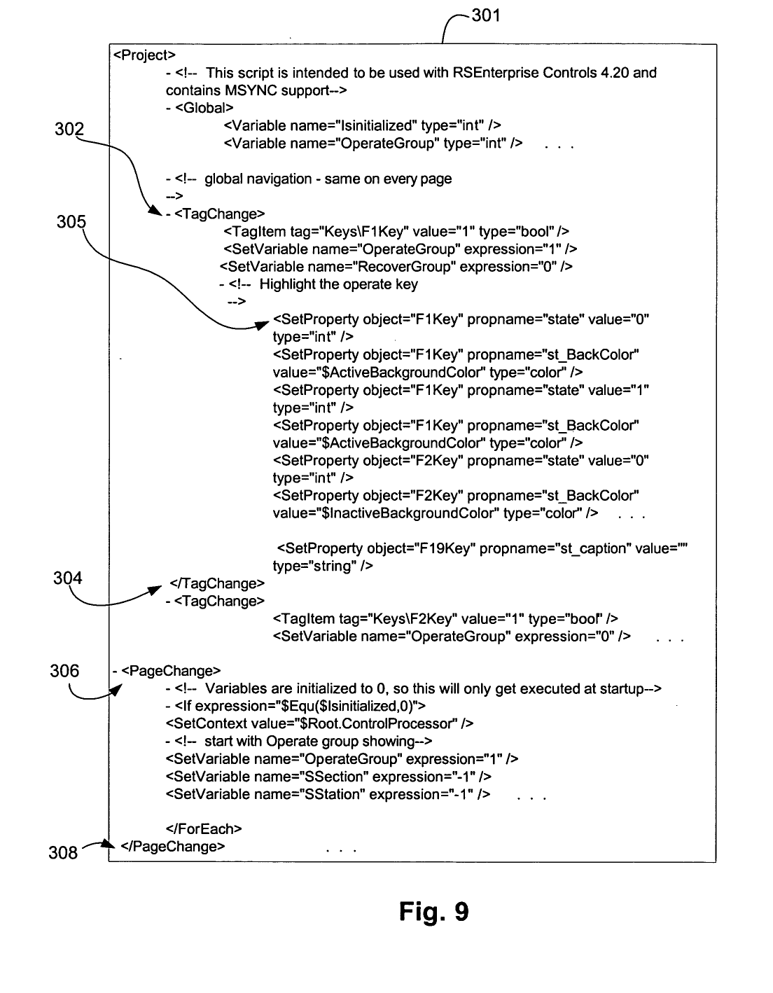

Referring to FIG. 8, an exemplary section of a project file 250 is illustrated that includes lines of information. Among other information illustrated, file 250 includes a line 254 that specifies a control processor that has an addressable ID number (i.e., 306662) at line 256 and a name at line 258 (i.e., Weld 1). File 250 also specifies that processor Weld 1 includes sections with line 260 and, consistent with the present example, specifically specifies sections Sec001 and Sec002 as shown at lines 262 and 270, respectively. In FIG. 8 sections Sec003 and Sec004 are not shown due to limited space. Line 252 indicates that section Sec001 is associated with the control processor having ID number 306662 which, as indicated above and in FIG. 8, is the Weld 1 processor. A similar line 269 indicates association between section Sec002 and the Weld 1 processor. File 250 further specifies that section Sec001 includes stations with line 264 and specifically specifies stations STA001A and STA001B at lines 266 and 268. Other more detailed information is contemplated and indeed currently is generated for the purpose of controller code development. Thus, project files include a substantial amount of built in information so that, after compilation, the amount of work required to complete controller code development is minimal.

After a project file is completely specified, a general language compiler is used to glean information from the project file and use that information to generate a general language control program such as a well known relay ladder logic (RLL) program. The general language program is then in turn compiled to generate the control code to be run by a controller (e.g., 26, 30, etc.) to control associated automated system resources. Alternately, the output from the compiler can be used to populate tables used by a table drive interpreter running in the controller.

In the present example it will be assumed that a separate project file 34 is initially provided for each controller 26, 30, etc. where the controller specific project file corresponds to automated system resources to be controlled by the associated controller. Thus, for instance, because controller 26 is provided to control station resources corresponding to sections 001 and 002, a first project file 34 corresponds to station resources associated with sections 001 and 002. Similarly, consistent with the example described above, a second project file corresponds to station resources associated with sections 003 and 004.

These intermediate data constructs or project files, in addition to being used by a compiler to glean information necessary for generating control code, are also useable to generate HMI programs. Here, as in the case of the controller code generating process described above, in at least some inventive embodiments, an HMI software generating compiler may be programmed to glean information from the project file that is useful in generating an HMI program for controlling/monitoring station resources associated with the project file. The process of gleaning project file information necessary for instantiating interfaces is described in greater detail below.

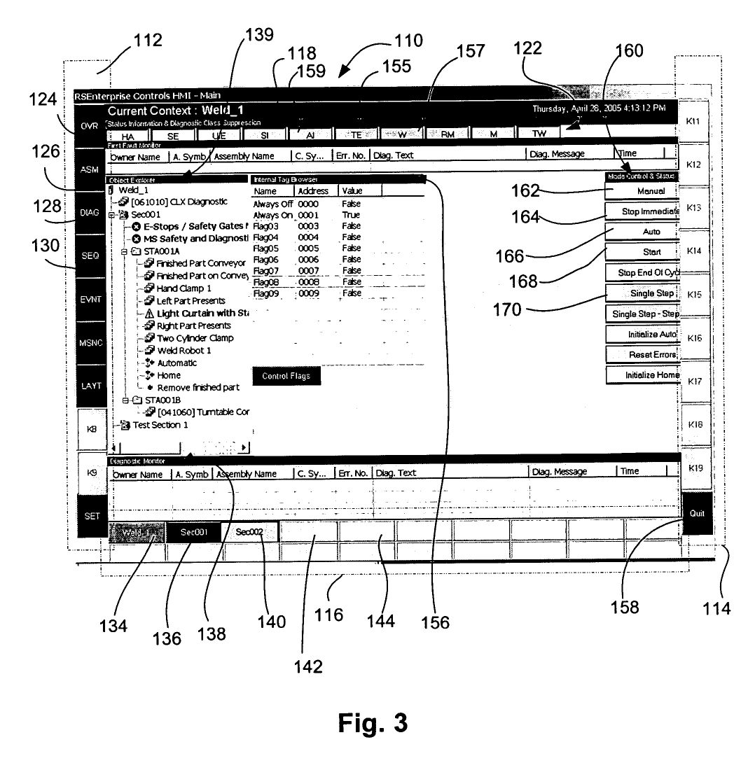

In addition, referring again to FIG. 1, at least some inventive embodiments enable a workstation 14 user to customize or specify interface templates 40 for subsequent use by the HMI software generating compiler. For instance, in at least some cases server 12 may run template defining program 35 to provide template defining tools via workstation 14 that enable an operator to specify on screen button icons, icon shapes, sizes, colors, locations, spatial relationships to other on-screen icons and text, icon labels, text font, text size, text color, changes in icon appearance when an activation activity occurs or to indicate different conditions related to the button, information presentation changes to occur when specific inputs is received via the interface (i.e., tag and page changes, etc.), etc. Referring also to FIG. 3, an exemplary HMI screen shot 110 that may be presented to an operator via interface 24 during operation of automated system 44 is illustrated. Exemplary HMI button icons include an overview button icon 124, an assembly view button icon 126, a quit button icon 158, etc.

Similarly, the template defining tools may enable an operator to specify on-screen indicator icons and related characteristics (i.e., size, shape, color, etc.), other input type icons including icons that simulate rotational selector knobs, slide type buttons, etc. In FIG. 3, exemplary HMI indicator icons include a “time out error” indicator icon 155, a “warning” icon 157, etc. Hereinafter, unless indicated otherwise, button and indicator icons will simply be referred to as buttons and indicators, respectively.

Moreover, template defining software 35 enables the operator to specify specific functions associated with on-screen buttons and indicators. For example, a “sequence view” button 130 (see FIG. 3) may be specified that is selectable to indicate that a sequence type view of a subset of system resource activities should be displayed. Here, the template defining tool is useable to link the sequence view button with the sequence view function. As another example, the “time out” error indicator 155 may be specified that, when highlighted, is to indicate that a time out error has occurred. Here, the template defining tool is used to link the time out indicator to the time out indicating function.

In at least some cases it is contemplated that the template defining software will present precanned functions and associated code that can be associated with buttons/indicators by the operator. For instance, the sequence view function may be a precanned function to be associated with a button that an operator specifies while a time out error function may be a precanned function to be associated with a time out indicator icon.

In at least some embodiments the template defining program will include drop down lists including descriptive labels associated with precanned functional code segments and the process of associating precanned functional code with buttons/indicators will be as simple as selecting a button/indicator on a template screen shot, accessing a drop down menu and selecting a descriptive label associated with the desired precanned functional code segment. In the alternative, in at least some cases a descriptive label associated with a precanned functional code segment may be selected first and then associated button/icon characteristics may be specified.

Furthermore, in at least some embodiments the template defining software will include reusable software components such as Active-X controls or JavaBean controls (i.e., dynamic software components) that can be selected and positioned on an interface screen to perform various functions where the reusable software components include precanned information presentation formats (e.g., buttons, indicators, data output formats, etc.) as well as related functional code segments. For instance, an Active-X control may be provides to support a diagnostics reporting function (i.e., reporting of dynamic information) that, as the label implies, provided feedback to an HMI user regarding diagnostics associated with system resources corresponding to the HMI. Referring again to FIG. 3, exemplary screenshot 110 includes a diagnostic monitor section 138 associated with a diagnostics reporting Active-X control. Other exemplary sections of screen shot 110 that may be related to function specific Active-X controls include an object explorer section 139, an internal tag browser section 156 and a mode control and status section 160.

Object explorer section 139 includes an automated system directory that corresponds to a subset of automated system resources. In FIG. 3, the directory corresponds to all resources associated with controller 24 (see again FIG. 1). Tag browser section 156 includes a list of system tags related to a subset of system resources. In FIG. 3, the list corresponds to resources associated with controller 24.

Mode control and status section 160 includes, as the label implies, control and status indicators/buttons for controlling and identifying control status of system resources. To this end, section 160 includes a manual mode selecting button 162, an immediate stop selecting button 164, an automatic mode selecting button 166, a start button 168, a single step button 170 and other exemplary control buttons. Each of the buttons/indicators in section 160 is associated with a separate precanned functional code segment specified in an Active-X control and designed to cause an HMI processor to perform the associated function. The functions of the section 160 buttons/indicators are well known in the controls art and therefore are not described here in detail. The point here is that when the Active-X control associated with section 160 is specified as part of a template, the entire on-screen appearance of section 160 and functional code segment associations are precanned and ready to go.

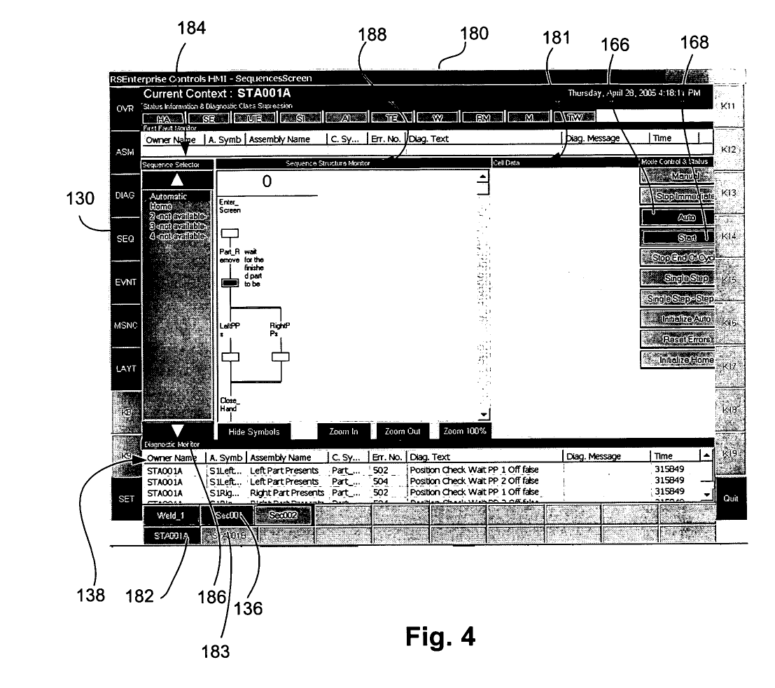

Referring still to FIG. 3, in addition to the exemplary screenshot buttons, indicators and features described above, other features include view selection buttons in a left edge column 122, control buttons in a right edge column 114 and diagnostic indicators arranged in a top edge row 122. The view selection icons include the overview button 124, the assembly view button 126, a diagnostics view button 128 and the sequence view button 130 described above, etc. As the “view” qualifier implies, each of icons 124, 126, 128, 130, etc., is selectable to display a different view of automated assembly resource information. For instance, while the directory and list of sections 139 and 156, respectively, may be displayed when overview button 124 is selected, a process sequence akin to a process flow chart for specific system resources may be displayed when sequence view button 130 is selected. To this end, referring to FIGS. 1 and 4, an exemplary sequence view 188 is illustrated in FIG. 4. Sequence view 188, as the label implies, provides a view that includes sequential process steps in a flow chart form for observation. In FIG. 4, screenshot 180 is shown after sequence view button 130 has been selected as well as additional on-screen buttons including a section 001 button 136 and a station 001A button 182 that indicate the subset of automated system resources for which the sequence view is to be presented. Here, the code that provides sequence view section 188 may be provided via another Active-X control.

In addition, screenshot 180 shows that automatic mode button 166 and start button 168 have been selected (i.e., buttons 166 and 168 are highlighted) to start a station 001A cycle corresponding to view 188. Moreover, screenshot 180 includes two other Active-X control sections 181 and 184 that have, to this point, not been discussed. Section 181 is provided so that when one of the cells is selected in sequence view 188, information (activities, status, etc.) related to the selected cell can be displayed. Section 184 is provided so that an HMI operator can step through resource sequences. In FIG. 4, as a sequence is performed, diagnostics information is reported via diagnostic monitor section 138.

Referring to FIG. 3, a quit function and corresponding label have been associated with a bottom button in section 114. In sections 112 and 114, the buttons labeled K8, K9 K11, etc., have not been assigned project file specific functions. Diagnostics indicator row 122 includes indicators for indicating different diagnostic types as those types occur. For instance, TE indicator 155 is associated with a timeout error function, W indicator 157 is associated with a warning error function, AI indicator 159 is associated with an assembly interlock error function, etc. Thus, when an error of a specific type occurs, an associated one of the indicators in row 122 is highlighted.

Here it should be appreciated that virtually any desirable interface function or section (e.g., layout of associated buttons like the buttons associated with mode control and status section 160) may be supported by a precanned Active-X control, a JavaBean control or some other similar reusable code structure and how many functions and interface sections are precanned is, at least to some extent, a matter of choice for a software engineer that programs the template defining software. Nevertheless, as a general rule, where certain functions and looks and feels of on screen information associated with these functions are likely to be universally desirable (at least in the context of applications in which an instance of the template defining software is to be used (e.g., in a single manufacturing facility or related facilities)), those functions and related on-screen information should be precanned as reusable software components to expedite the template specifying task as well as to force standard preferred or consistent HMI appearances and/or functions.

According to another inventive aspect of at least some embodiments of the invention, a scripting language has been developed that is tailored for HMI template specification requirements. In this regard, the HMI scripting language has built in event based constructs for handling interaction with HMI objects such as screens, push buttons, tags, etc. The event based constructs include two general types including page change events and tag change events. Page change events handle computations and formatting required when an interface user causes the interface to move from one display screen to another such as, for instance, when the information view type is changed. Tag change events handle information changes that occur when an interface user interacts with push buttons or other on-screen selectable objects/icons that do not cause complete screen changes. For instance, while information including a stop button associated with a first station is presented via an interface, a user may select the stop button to cause station activity to be halted. Here, button selection changes the state of the button and results in some activity but the screen presented is not altered by changing to a completely different screen (i.e., to a different page).

In at least some embodiments the HMI scripting language used to script portions of an HMI template uses the syntax of an Xtensible Markup Language (XML). By adopting XML syntax, off the shelf tools are usable to write the scripts required to support HMI requirements and the resulting scripts can be compressed very effectively as well known in the XML programming art. The end result is that using the HMI scripting language HMI templates can be developed that are usable to produce HMI programs that require less memory than interfaces developed with other general scripting languages (i.e., VisualBasic) and thus the resulting interface programs can be used to drive many different types of HMIs including HMIs that have limited memory capabilities.

Referring now to FIG. 9, an exemplary section 301 of HMI template script is illustrated that includes a tag change event construct as well as a page change event construct that are consistent with at least one inventive embodiment. Consistent with XML syntax, the tag event construct indicates the beginning of script associated with a tag change via a label <TagChange> 302 and the end of a tag change via a label </TagChange> 304. Between labels 302 and 304 HMI objects (e.g., buttons, tags, etc.) are specified along with various attributes including tags, property names, values and types which again are expressed in a syntax that is consistent with XML (i.e., the form is “<. . . />”). At 305 it can be seen that specific a specific HMI object, the F1 key, is directly linkable to a tag change event construct which makes the developed HMI scripting language extremely powerful. Similarly, consistent with XML syntax, the page change event construct indicates the beginning of script associated with a page change via a label <PageChange> 306 and the end of a tag change via a label </PageChange> 308. Between labels 306 and 308 HMI page information is specified along with various attributes including property names, values and types which again are expressed in a syntax that is consistent with XML.

While it is often advantageous to employ several Active-X controls on a single display screen as illustrated in FIG. 3, one problem with employing multiple controls on a single screen is the speed with which such screens can be generated. To this end, most Active-X controls require at least some information from a project file to perform their associated functions (i.e., display of diagnostic information, display of a sequence flow diagram, etc.). In addition, when a screen is accessed that requires an Active-X control, the control is newly created and, similarly, when the screen is closed, the Active-X control is destroyed. Thus, each time an Active-X control is required, an interface processor has to re-glean information form the project file to instantiate the control on the screen. It has been found that re-gleaning information from a project file is time consuming and that the time required to re-glean information for multiple Active-X controls can result in sever performance problems (i.e., when a screen is to be displayed and several Active-X controls need to be created and instantiated, it requires a noticeable amount of time to read the information and hence the screen is not immediately displayed). Similarly, it has been found that detailed scripting that requires access to project file information also can hinder HMI performance for similar reasons.

To overcome these performance problems, according to at least one aspect of at least some inventive embodiments, referring again to FIG. 1, a run time database 300 is created by HMI processor 27 for storing information gleaned from a project file for instantiating Active-X controls as well as scripted sections of an HMI template where information in database 300 can be accessed much more quickly than information in the project file. Here, during system operation, when an HMI screen is first accessed that requires an Active-X control or control associated with a scripted section of an HMI program, processor 27 gleans the information required from the project file to instantiate the control and instantiates the control. Thereafter, processor 27 stores the gleaned information in database 300 in an easily accessible fashion so that the next time the same Active-X control or control associated with the scripting is required, processor 27 can simply access database 300 and directly obtain the instantiating information instead of having to re-glean the required information. This process of storing information required by Active-X controls and controls associated with scripted code sections substantially improves HMI performance.

Rockwell Software, Inc. currently produces and sells a RSView software package that is useful for configuring individual HMI programs. Here, it is contemplated that the RSView package or a similar software package may be modified to provide the template defining program 35. In this regard, the RSView package includes many of the template specifying tools that are described above as well as additional tools. There are two primary modifications RSView that are useful to generate HMI templates. First, at least some specified features should to be assigned functions that cannot be associated with system specific resources until after resource characteristics have been gleaned from a project file associated with the resources. Second, in at least some embodiments, an HMI scripting language like the language described above with respect to FIG. 9 should be provided so that HMI type scripting is easy to perform. With respect to assigning functions to be subsequently associated, referring again to FIG. 1, while exemplary controller 26 is programmed to control automated system sections 001 and 002, other controllers (e.g., 30) will be programmed to control other system sections and perhaps different numbers of sections. While section selecting buttons may be required on each HMI in a facility that are selectable to access section related information, the number of section buttons required on each HMI cannot be known at the template defining stage and can only be known after section labels and related information is gleaned from a project file.

Referring again to FIG. 3, screenshot 110 includes section 115 along a lower edge that includes upper and lower rows of ten buttons (i.e., the rows include a total of twenty buttons) several of which are labeled 134, 136, 140, 142, 144, etc. In the illustrated example, it is assumed that the template defining software includes controller, section and station selecting pre-canned functions that are associable with on-screen buttons. It will also be assumed that the controller, section and station selecting functions can be associated with buttons prior to knowing which, if any, controller, section or station may be associated with the button.

Referring still to FIG. 3, in the present example it will further be assumed that, after the twenty buttons in section 115 are specified, a workstation 14 operator links the controller selecting function to button 134 (i.e., the first button in the upper row), a separate instance of the section selecting function to each of the second through tenth buttons in the upper row and a separate instance of the station selecting function to each of the ten buttons in the lower row. Initially, prior to instantiating an HMI program, each of the buttons in section 115 of the template appears blank like buttons 142, 144, etc. Subsequently, when an HMI program is instantiated, controller, section and station labels are associated with appropriate buttons in section 115. Thus, in at least some inventive embodiments, specific on screen features or spaces and associated functions of templates are reserved as place holders to be correlated with project file specific information to be subsequently gleaned.

In FIG. 3, a controller label “Weld 1” and section labels Sec001 and Sec002 have been added to buttons 134, 136 and 140, respectively, that are selectable to select different automated system resource subsets for which information should be displayed. In FIG. 3, Weld 1 button 134 is shown highlighted to indicate that button 134 has been selected and hence sections 139, 156, etc. include information associated with the Weld 1 controller. To observe section specific information, an HMI user can simply select one of section selecting buttons 136 or 140. Referring again to FIG. 4, as described above, screenshot 180 shows an HMI screenshot after section 001 button 136 has been selected (which causes buttons 182 and 183 corresponding to stations that comprise section 001 to be displayed) and after station 001A button 182 has been selected.

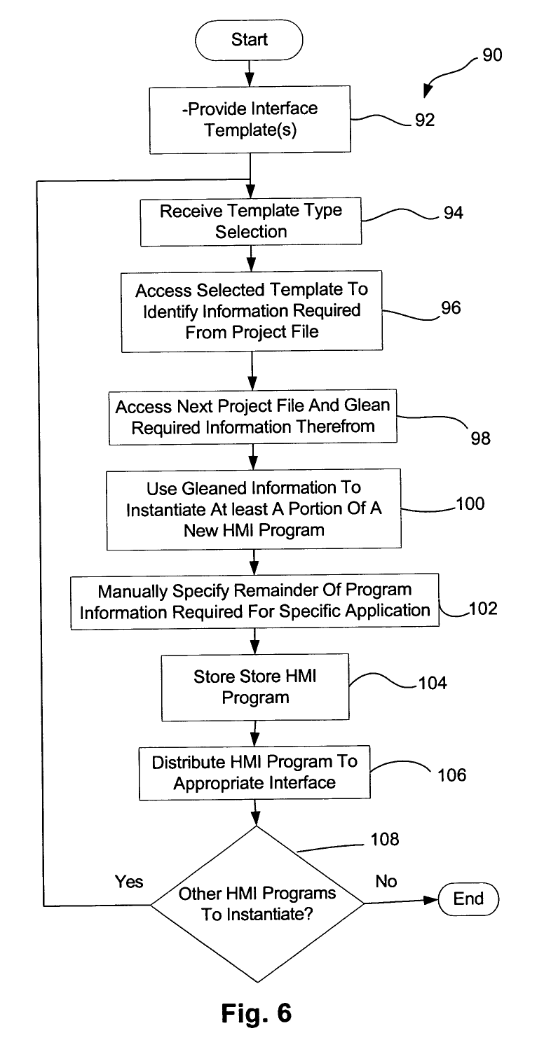

Referring now to FIG. 5, a simple method 70 for defining or specifying an HMI template according to at least some inventive embodiments is illustrated.

Referring also to FIG. 1, at process block 72, a workstation 14 operator accesses template defining program 35 and the interface components library 38 stored in database 22. At block 74, the operator uses workstation 14 to configure an interface template by identifying required buttons, indicators, button/indicator looks and feels, Active-X controls, arrangement of the various selected and specified components, functions associated with buttons and indicators, scripting required to support HMI activities associated with HMI objects, etc. As described above, one useful software package for template defining is the RSView software package that is modified so that place holder functions and features are specifiable and so that HMI scripting software consistent with the description above is available for scripting requirements.

Referring still to FIGS. 1 and 5, after the workstation operator completely specifies an HMI template at block 74, at process block 76 the operator causes server 12 to store the HMI template (see 42 in database 22). At block 78, where other templates are to be defined or specified, control passes back up to block 72 where the process including block 72, 74 and 76 continues. If no other HMI templates are to be defined at block 78, then the template defining process is completed.

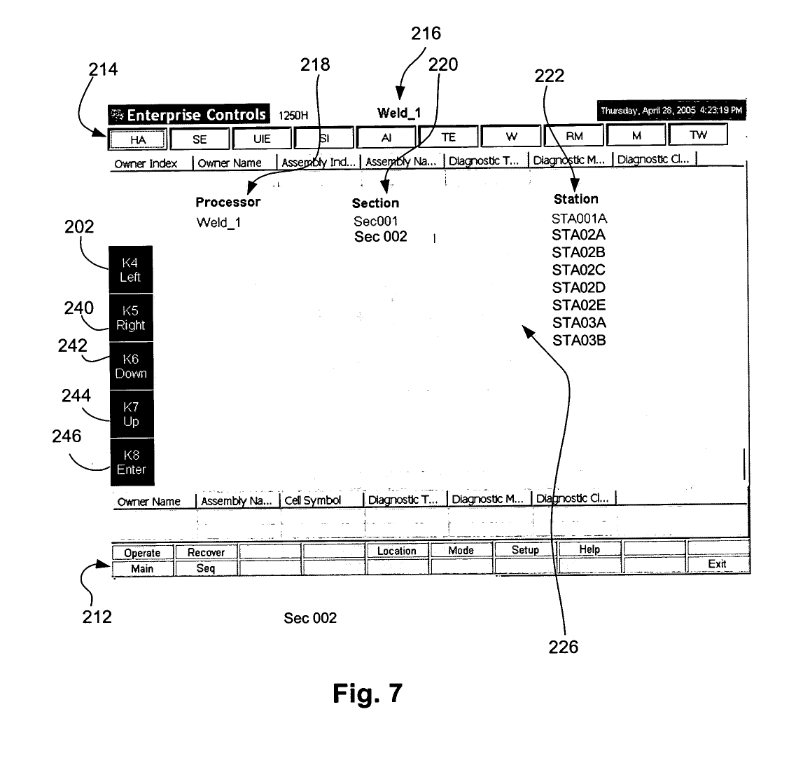

Referring now to FIG. 6, a method 90 for instantiating HMI programs using HMI templates is illustrated. Referring also to FIG. 1, prior to block 92 it is assumed that at least one interface template has been defined and stored in database 22 and that a project file associated with the system resources corresponding to system sections 001 and 002 (i.e., corresponding to the resources controlled/monitored by controller 24) is also stored in database 22. Referring also to FIG. 1, to instantiate an HMI program for controlling/monitoring the section 001 and 002 resources, at block 92, a system operator uses workstation 14 to access a list of the interface template types. At block 94, the operator selects one of the template types from library 40. In the present example it will be assumed that the operator selects a template that is consistent with the appearance of and functions related to screenshot 110 in FIG. 3.

Continuing, at process block 96, server 12 accesses the selected template to identify information required from the project file 34 to instantiate an HMI program that is consistent with the template. For example, at block 96, server 12 may identify information required to instantiate an interface instance that includes a project label, section labels, station labels, control assembly labels, controller memory addresses associated with the various labels, the relationships between the different labeled components and component subsets, etc. At block 98, server 12 accesses the project file 34 and gleans the required information therefrom for instantiating an HMI program. At block 100, server 12 uses the gleaned information to instantiate at least a portion of an HMI program.

Instantiation in the present context and in at least some embodiments includes populating features of the template with information gleaned from the project file. For instance, in the example illustrated in FIG. 3, gleaned labels Weld 1, Sec 001 and Sec 002 are provided on buttons 134, 136 and 140, respectively and data tables including input and output addresses associated with the controller and sections 001 and 002 in the project file are associated with the functions corresponding to buttons 134, 136 and 140, respectively. Similarly, addresses of information to be displayed via the reusable software components (e.g., the Active-X controls) such as sections 138, 134, 155, etc., are associated with buttons 134, 136, 140, etc. and/or combinations of various screen selectable buttons. While these examples of instantiation are extremely simple, it should be appreciated that an actual instantiation process would be much more voluminous.

Next, at block 102, the system operator uses workstation 14 to, if necessary, manually specify additional information that is required in a specific application to generate a complete HMI program. For example, in at least some cases, a facility in which automated system 44 is located may require an overview of CAD drawings associated with a machine line that includes fault indicators laid out over the drawings. Here, the RSView software package does not facilitate generation of such CAD drawings with fault indicators and therefore some additional manual programming or interface configuring is required. In most cases it is believed that the additional manual specifying process will be minimal at best (e.g., the automatic HMI software may generate 95% of required HMI features).

Referring still to FIGS. 1 and 6, at block 104 the instantiated HMI program is stored in database 22. At block 106, server 12 distributes the instantiated HMI program to the appropriate HMI 24, 28, etc. which loads the software. At block 108, when additional HMI programs are to be instantiated, control passes back up to block 94 where the process described above is repeated a separate time for each additional program. After block 108, if all of the HMI programs that are necessary have been completely specified and distributed, the process is terminated.

While the invention may be susceptible to various modifications and alternative forms, specific embodiments have been shown by way of example in the drawings and have been described in detail herein. However, it should be understood that the invention is not intended to be limited to the particular forms disclosed. For example, while a template defining method and an HMI program generating method have been described above, it should be appreciated that aspects of each one of those methods may in and of themselves be inventive. For example, in at least some cases where templates already exist, the HMI program generating method is believed to be independently patentable. Similarly, use of an interface for specifying an HMI program type template for use as described above is also believed to be independently patentable.

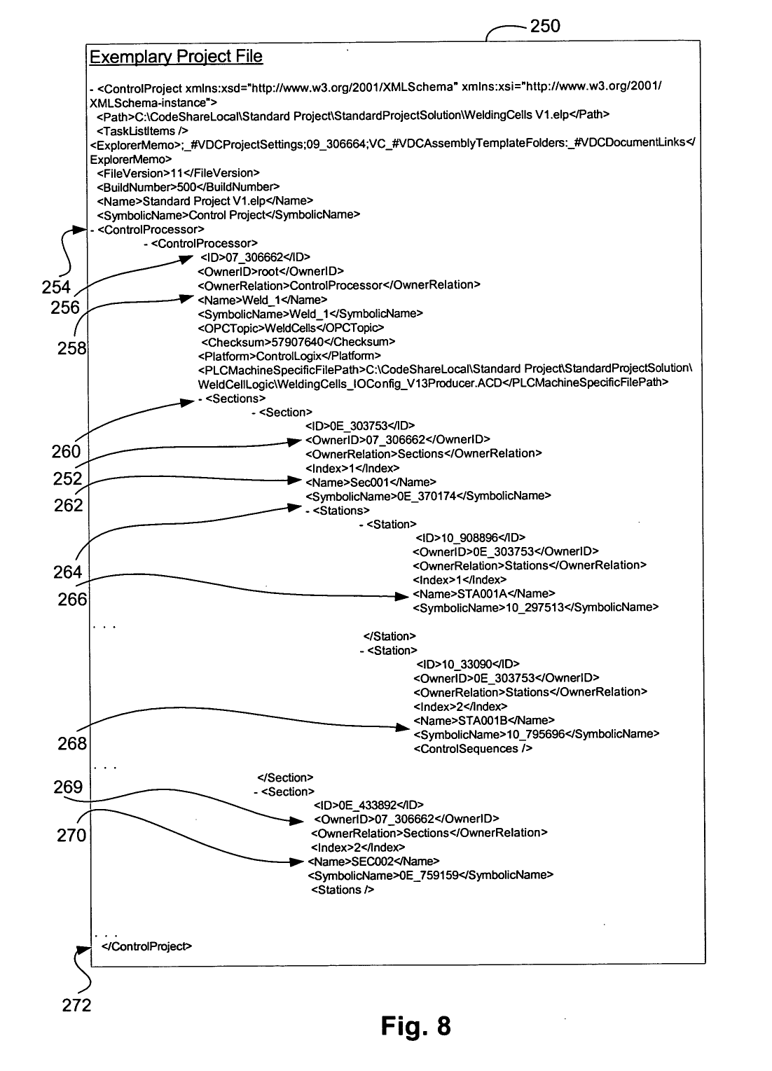

In addition, while one type of template and corresponding screenshots associated with an interface have been described above with respect to FIGS. 3 and 4, other template types and HMI programs that have different characteristics are clearly contemplated. To this end, an exemplary screen shot 216 that is consistent with a second template type and associated HMI program that may be generated using the methods described above as illustrated in FIG. 7. Screen shot 216 includes a subset of the information and controls described above with respect to screenshot 110 and may be more suitable for use with a smaller interface display screen 24 (see again FIG. 1). To this end, screenshot 216 includes a row 214 of diagnostic type indicators, a navigation section 226 that includes three rows of assembly resource information including a processor row 218, a section row 220 and a station row 222, navigation buttons or keys for navigating among the information in section 226, the navigation buttons including left, right, down, up and enter buttons 202, 240, 242, 244 and 246, respectively, and various control and view buttons provided in a section 212 near the lower edge. The number of different types of HMI programs and associated looks and feels that can be configured is virtually limitless.

Moreover, while a useful HMI scripting language is described above, it should be appreciated that at least some inventive embodiments do not require such a scripting language and that more conventional scripting languages (i.e., VisualBasic) could be used to develop templates. In addition, it is believed that the HMI scripting language itself that includes built in event based constructs for interacting with HMI objects (e.g., on screen selectable button icons, tags, etc.) is novel.

Thus, the invention is to cover all modifications, equivalents, and alternatives falling within the spirit and scope of the invention as defined by the following appended claims. To apprise the public of the scope of this invention, the following claims are made:

What is claimed is:

1. A method for configuring an interface for use with an automated system including at least a first controller that runs a first system program to control and monitor automated system components, a first project file associated with the first system program and describing at least a subset of the system components and system operation, the method comprising the steps of:
providing an interface template that specifies interface components and arrangement of the interface components relative to each other for presentation on a display screen;
gleaning information from the first project file regarding input and output parameters to be supported by an interface; and
instantiating an instance of an interface using the interface template and the information gleaned from the first project file.

2. The method of claim 1 wherein the step of providing an interface template includes specifying at least a first subset of interface inputs to be provided irrespective of the contents of the first project file, the step of instantiating an interface instance including linking each of the interface inputs in the subset to a separate selectable input component.

3. The method of claim 2 wherein the step of providing an interface template includes specifying a separate screen selectable icon for each of the first sub-set of interface components, the step of instantiating including providing an interface instance including the separate screen selectable icons as the selectable input components and linking the interface inputs to the input components.

4. The method of claim 3 wherein the step of providing an interface template includes specifying a separate label for each of the separate screen selectable icons, the step of instantiating further including scripting the labels to associated screen selectable icons.

5. The method of claim 2 wherein the step of providing an interface template includes providing software code for presenting at least first and second different view types of automated system components and specifying a separate interface input for each of the first and second different view types.

6. The method of claim 2 wherein the step of providing an interface template includes providing software code for controlling automated system operation and specifying a separate interface input for each of a plurality of different control functions.

7. The method of claim 2 wherein the step of providing an interface template includes providing software code for receiving operating parameter output values from the automated system and presenting different diagnostic message types related to operating parameter values and specifying a separate interface input for each of a plurality of different diagnostic view types.

8. The method of claim 1 wherein the project file specifies a plurality of distinct automated system control assemblies wherein the step of providing an interface template includes providing a template that specifies a subset of input components that may be associated with control assemblies, the step of gleaning including identifying control assemblies specified by the project file, the step of instantiating including associating a separate one of the control assembly input components with each gleaned project file control assembly.

9. The method of claim 8 wherein the project file includes control assembly labels and system addresses, the step of gleaning including identifying control assembly labels and associated addresses, the step of instantiating includes scripting each control assembly label to a separate one of the control assembly input components and associating the control assembly input components with corresponding system addresses.

10. The method of claim 8 wherein the first system program monitors at least a sub-set of system operating parameters and generates output values associated therewith, the step of providing an interface template including providing a template having at least a first template section that is associated with a reusable software component that actively reports output values associated with at least a subset of the operating parameters, the operating parameters displayed by the interface instance at any given time being a function of which control assembly input component is selected.

11. The method of claim 1 wherein the first system program monitors at least a sub-set of system operating parameters and generates output values associated therewith, the step of providing an interface template including providing a template having at least a first template section that is associated with a reusable software component that actively reports output values associated with at least a subset of the operating parameters.

12. The method of claim 11 wherein the reusable software components are one of Active-X components and Java Beans components.

13. The method of claim 1 wherein the project file specifies a plurality of distinct automated system control assemblies and the first system program monitors at least a sub-set of system operating parameters and generates output values associated therewith, the step of providing an interface template including providing software code for presenting at least first and second different view types of automated system components and specifying a separate view type input for each of the first and second different view types, providing software code for controlling automated system operation and specifying a separate control input for each of a plurality of different control functions, providing software code that specifies a subset of input components that may be associated with control assemblies and specifying at least a first template section that is associated with a reusable software component that actively reports output values associated with at least a subset of the operating parameters, the step of gleaning including identifying control assemblies specified by the project file and the step of instantiating including associating a separate one of the control assembly input components with each gleaned project file control assembly, wherein the operating parameters displayed by the interface instance at any given time are a function of which control assembly input is selected, which view type input is selected and which control input is selected.

14. The method of claim 13 wherein the step of providing an interface template further includes providing software code for receiving operating parameter output values from the automated system and presenting different diagnostic message types related to operating parameter values and specifying a separate interface input for each of a plurality of different diagnostic view types, wherein the diagnostic information presented at any given time are a function of which control assembly input is selected, which view type input is selected, which control input is selected and which diagnostic view type is selected.

15. The method of claim 1 wherein the at least a first controller also runs a second system program to control and monitor automated system components where a second project file is associated with the second system program, the method further including the steps of gleaning information from the second project file regarding input and output parameters to be supported by a second interface and instantiating a second interface instance using the interface template and the information gleaned from the second project file.

16. A method for configuring interfaces for use with an automated system including at least a first controller that runs system programs to control and monitor automated system components, a plurality of project files associated with the system programs and describing at least a subset of the system components and system operation, the method comprising the steps of:
providing an interface template that specifies interface components and arrangement of the interface components relative to each other for presentation on a display screen;
for each of the project files:
gleaning information from the project file regarding input and output parameters to be supported by an interface; and
instantiating an instance of an interface using the interface template and the information gleaned from the project file such that a plurality of similar yet project file specific interface instances are instantiated.

17. A method for configuring an interface template for use in specifying at least one interface for use with an automated system including a controller that runs a system program to control and monitor automated system components, the method comprising the steps of:
providing a library of possible interface components;
providing a template specifying interface;
using the template specifying interface to select interface components from the library and to spatially arrange the selected components with respect to each other to form an interface template; and
storing the interface template for subsequent use in configuring interfaces.

18. The method of claim 17 wherein the step of providing a library of possible interface components includes providing at least some dynamic components that include program code for monitoring automated system operating parameters and presenting dynamic information related thereto.

19. The method of claim 18 wherein the dynamic components are one of Active-X components and Java Beam components.

20. The method of claim 17 wherein automated system information can be arranged according to several different view types and wherein the step of providing a library of possible interface components includes providing at least some components that include program code for altering view type.

21. The method of claim 17 wherein automated system information can be arranged according to several different view types and wherein the step of providing a library of possible interface components includes providing at least some components that include program code for altering view type.

22. The method of claim 17 also for configuring instances of interfaces for use with the automated system wherein the system includes at least a first controller that runs a system program to control and monitor automated system components, a project file associated with the first system program and describing at least a subset of the system components and system operation, the method further including the steps of, gleaning information from the project file regarding input and output parameters to be supported by an interface and instantiating an instance of an interface using the interface template and the information gleaned from the project file.

23. The method of claim 17 wherein the step of providing a library includes providing code segments associated with specific functions, the method further including the step of, prior to storing, using the template specifying interface to associate functions with specific selected components.

24. An apparatus for configuring an interface for use with an automated system including at least a first controller that runs a first system program to control and monitor automated system components, a first project file associated with the first system program and describing at least a subset of the system components and system operation, the apparatus comprising:
a database including at least a first interface template that specifies interface components and arrangement of the interface components relative to each other for presentation on a display screen;
a processor linked to the database and programmed to perform the steps of:
gleaning information from the first project file regarding input and output parameters to be supported by an interface; and
instantiating an instance of an interface using the interface template and the information gleaned from the first project file.

25. An apparatus for configuring an interface template for use in specifying at least one interface for use with an automated system including a controller that runs a system program to control and monitor automated system components, the apparatus comprising:
a database including a library of possible interface components;
an interface for selecting interface components from the library and spatially arranging the selected components with respect to each other to specify interface template information;
a processor programmed to perform the steps of:
receiving the interface template specifying information;
instantiating an instance of the interface template; and
storing the interface template specifying information for subsequent use in configuring interfaces.

26. A method for providing an interface screen including reusable software components that require information from a project file to be instantiated, the method comprising the steps of:
identifying information required b the reusable software components for instantiation;
storing the required information in a database;
when a screen is accessed that includes the reusable software component, accessing the database to obtain the information needed for instantiation; and
instantiating the reusable software component.

27. The method of claim 26 wherein the reusable software components are one of Active-X controls and Java Bean controls.

28. A method for programming an HMI display device that includes HMI objects, the method comprising the steps of:
providing an HMI scripting language that includes event based constructs that are associable with HMI objects;
using the HMI scripting language to script at least a portion of an HMI program that associates at least a subset of HMI objects with event based constructs; and
using the HMI program to drive an HMI.

29. The method of claim 28 wherein the step of providing an HMI scripting language that includes event based constructs that are associable with HMI objects includes providing a language that at least one of includes tag change event constructs that cause interface activity as a consequence of a user interacting with an interface object and page change events that cause interface activity as a consequence of a user moving to a different HMI screen.
